(19) United States
(12) Patent Application Publication
(10) Pub. No.: US 2024/0274575 A1
(43) Pub. Date: Aug. 15, 2024

(54) LIGHTING DEVICE AND VEHICLE LAMP COMPRISING SAME

(71) Applicant: LG INNOTEK CO., LTD., Seoul (KR)

(72) Inventors: Kwang Hyun KO, Seoul (KR); Moo Ryong PARK, Seoul (KR); Dong Hyun LEE, Seoul (KR)

(21) Appl. No.: 18/290,895

(22) PCT Filed: Aug. 4, 2022
(86) PCT No.: PCT/KR2022/011513

§ 371 Date: Jan. 22, 2024

(30) Foreign Application Priority Data
Aug. 4, 2021 (KR) 10-2021-0102620

(51) Int. Cl. H01L 25/065; H01L 33/56; H01L 33/60

(52) U.S. Cl. CPC H01L 25/0655; H01L 33/56; H01L 33/60

(57) ABSTRACT

The lighting device disclosed at an embodiment of the invention comprises a substrate; a plurality of light emitting devices on the substrate; a resin layer disposed on the substrate and sealing the light emitting devices; and a diffusion layer on the resin layer, wherein the resin layer includes a plurality of recess portions that are concave toward each of the plurality of light emitting devices, the diffusion layer includes a plurality of protruding portions disposed in each of the plurality of recess portions, each of the plurality of protruding portions is spaced apart in a first direction in which light is emitted from each light emitting device, a maximum depth of each of the plurality of recess portions is less than a maximum width in at least one direction perpendicular to the first direction, and a thickness of the resin layer may be smaller than the maximum width of each recess portion and greater than the maximum depth of each recess portion.

### TECHNICAL FIELD

An embodiment of the invention relates to a lighting device having a light emitting device.

An embodiment of the invention relates to a lighting module providing a surface light source, a light unit having a lighting module, or a vehicle lamp.

### BACKGROUND ART

Typical lighting applications include vehicle lights as well as backlights for displays and signs. Light emitting device, such as light emitting diode (LED), have advantages such as low power consumption, semi-permanent life, fast response speed, safety, and environmental friendliness compared to conventional light sources such as fluorescent lamps and incandescent lamps. These light emitting diodes are applied to various display devices, various lighting devices such as indoor or outdoor lights. Recently, as a vehicle light source, a lamp employing a light emitting diode has been proposed. Compared with incandescent lamps, light emitting diodes are advantageous in that power consumption is small. However, since an emission angle of light emitted from the light emitting diode is small, when the light emitting diode is used as a vehicle lamp, there is a demand for increasing the light emitting area of the lamp using the light emitting diode. Since the light emitting diode is small, it may increase the design freedom of the lamp, and it is economical due to its semi-permanent life.

### DISCLOSURE

### Technical Problem

An embodiment of the invention may provide a lighting device that has a thin thickness and provides a planar light source. An embodiment of the invention may provide a lighting device in which a resin layer covers a plurality of light emitting devices and a diffusion layer is disposed in a recess portion overlapping at least one light emitting device on an upper portion of the resin layer. An embodiment of the invention may provide a flexible lighting module having a plurality of light emitting devices, a resin layer, and a diffusion layer on a substrate. An embodiment of the invention may provide a lighting module that irradiates a surface light source, and a lighting device, light unit, display device, or vehicle lamp having the same.

### Technical Solution

A lighting device according to embodiment of the invention comprises a substrate; a plurality of light emitting devices disposed on the substrate; a resin layer disposed on the substrate and sealing the plurality of light emitting devices; and a diffusion layer on the resin layer, wherein the resin layer includes a plurality of recess portions that are concave toward each of the plurality of light emitting devices, the diffusion layer includes a plurality of protruding portions disposed in each of the plurality of recess portions, each of the plurality of protruding portions is spaced apart in a first direction in which light is emitted from each light emitting device, a maximum depth of each of the plurality of recess portions is less than a maximum width in at least one direction perpendicular to the first direction, and a thickness of the resin layer may be smaller than the maximum width of each recess portion and greater than the maximum depth of each recess portion.

According to an embodiment of the invention, a minimum distance from one side of the resin layer facing the substrate to the recess portion may be in a range of 0.7 to 1.5 times a thickness of the light emitting device. A sum of the thicknesses from one side of the resin layer to the other side of the diffusion layer in the first direction may be less than the maximum width or 2 mm or less. The maximum depth of each recess portion in the first direction may be in a range of 12% to 41% of an optical axis distance from one side of the resin layer to the other side of the diffusion layer in the first direction. Each of the recess portions may have a shape whose width increases from a region closest to each light emitting device to a distance from each light emitting device. The shape of each recess portion may have a hemispherical, a semi-elliptical shape, or a double curved shape in a side cross section.

According to an embodiment of the invention, the diffusion layer may include an extension portion connecting the plurality of protruding portions to each other on the resin layer. The diffusion layer may include a side portion extending to each side surface of the resin layer. The lighting device may include a reflective member disposed between the substrate and one surface of the resin layer.

A lighting device according to an embodiment of the invention includes a first reflective member; a second reflective member facing the first reflective member; a resin layer disposed between the first and second reflective members; a plurality of light emitting devices sealed in the resin layer and emitting light through one side between the first and second reflective members; and a diffusion layer disposed on a portion of the outer side of the resin layer, wherein the resin layer includes a plurality of recess portions that are concave from one side of the resin layer toward each of the plurality of light emitting devices, the diffusion layer includes a plurality of protruding portions disposed in each of the plurality of recess portions, each of the plurality of protruding portions is spaced apart in a first direction in which light is emitted from each light emitting device, a maximum depth of each of the plurality of recess portions is smaller than a maximum width in at least one direction perpendicular to the first direction, and a thickness of the resin layer may be smaller than the maximum width of each recess portion and greater than the maximum depth of each recess portion.

According to an embodiment of the invention, the diffusion layer includes an extension portion connecting the plurality of protruding portions, and the protruding portion and the extension portion may provide an exit surface through which the light is emitted. The diffusion layer may include side portions extending on both sides of the resin layer in a longitudinal direction. One end of the first and second reflective members and one end of the resin layer or the diffusion layer may be disposed on the same plane. The lighting device includes a substrate disposed under the first reflective member, and the plurality of light emitting devices may be mounted on the substrate. The lighting device includes a substrate disposed on the other side of the resin layer, and the plurality of light emitting devices may be mounted on the substrate.

A vehicle lamp according to an embodiment of the invention may have the lighting device disclosed above.

### Advantageous Effects

According to an embodiment of the invention, light uniformity of a surface light source may be improved. In an embodiment of the invention, a recess portion of the resin layer disposed on each light emitting device has a diffusion agent, so that incident light may be diffused. An embodiment of the invention may reduce hot spots on each light emitting device, may make a module or a device slim, and may be implemented as a flexible module. The optical reliability of the lighting module and the lighting device having the same according to an embodiment of the invention may be improved. It may be applied to vehicle lighting devices, light units, various display devices, and a lighting device of a surface light source having the lighting module according to embodiments of the invention.

### DESCRIPTION OF DRAWINGS

FIG. 1 is a plan view showing a lighting device according to a first embodiment of the invention.

FIG. 2 is a side cross-sectional view of the lighting device of FIG. 1.

FIG. 3 is a partially enlarged view of the lighting device of FIG. 2.

FIG. 4 is another example of the lighting device of FIG. 2.

FIG. 5 is another example of the lighting device of FIG. 4.

FIGS. 6 (A) and (B) are side cross-sectional views and a luminous intensity graph showing a modified example of the diffusion layer in the lighting device of FIG. 2.

FIGS. 7 to 9 are examples of diffusion layers of different shapes in a lighting device according to an embodiment of the invention.

FIG. 10 (A) shows that a recess portion of the lighting device in the embodiment of the invention has a polygonal shape, and (B), (C) and (D) is a diagram comparing the luminous intensity of the lighting device according to the depth of the recess portion of FIG. 10 (A).

FIG. 11 (A) shows that a recess portion of the lighting device in the embodiment of the invention has a semi-elliptical shape, and (B) and (C) is a diagram comparing the luminous intensity of the lighting device according to the depth of the recess portion in FIG. 11(A).

FIG. 12 (A) is a lighting device in a comparative example, and (B) is a diagram showing the luminous intensity of the lighting device in FIG. 12 (A).

FIG. 13 is a plan view of a lighting device according to a second embodiment.

FIG. 14 is a cross-sectional view along the line A-A of the lighting device of FIG. 13.

FIG. 15 is a side view of the lighting device of FIG. 13 and is another example.

FIG. 16 is a diagram showing the manufacturing process of the lighting device of FIG. 2.

FIG. 17 is an application example of a lamp having a lighting device according to an embodiment of the invention.

FIG. 18 is a plan view of a vehicle to which a lamp having a lighting device according to an embodiment of the invention is applied.

FIG. 19 is a diagram showing a lamp having a lighting device according to an embodiment of the invention.

### BEST MODE

Hereinafter, with reference to the attached drawings, preferred embodiments through which the present invention may be easily implemented by those skilled in the art will be described in detail. However, it should be understood that the embodiments described in this specification and the configurations shown in the drawings are only preferred embodiments of the present invention, and there may be various equivalents and modifications that can replace them at the time of filing the present application. In describing the operating principle of a preferred embodiment of the present invention in detail, when it is determined that a detailed description of a related known function or configuration may unnecessarily obscure the gist of the present invention, the detailed description will be omitted. The terms described below are terms defined in consideration of their functions in the present invention, and the meaning of each term should be interpreted based on the content throughout the present specification. The same reference numerals are used for parts with similar functions and actions throughout the drawings.

The lighting device according to the present invention may be applied to various lamp devices that require lighting, such as vehicle lamps, household lighting devices, and industrial lighting devices. For example, when applied to vehicle lamps, it may be applied to head lamps, side lights, side mirror lights, fog lights, tail lamps, brake lights, daytime running lights, vehicle interior lights, door scars, rear combination lamps, backup lamps, etc. The lighting device of the invention can be applied to indoor and outdoor advertising devices, display devices, mobile devices, and various electric train fields. In addition, it may be applied to all lighting-related fields or advertising-related fields that are currently developed and commercialized or that may be implemented according to future technological development. Hereinafter, embodiments will be clearly revealed through the accompanying drawings and description of the embodiments. In the description of the embodiments, when each layer (film), region, pattern, or structure is described as being formed on or under the substrate, each layer (film), region, pad, or pattern, “on” and “under” include both “directly” or “indirectly” through other layers. In addition, the criterion for the top or bottom of each layer will be described based on the drawings.

### <Lighting Device>

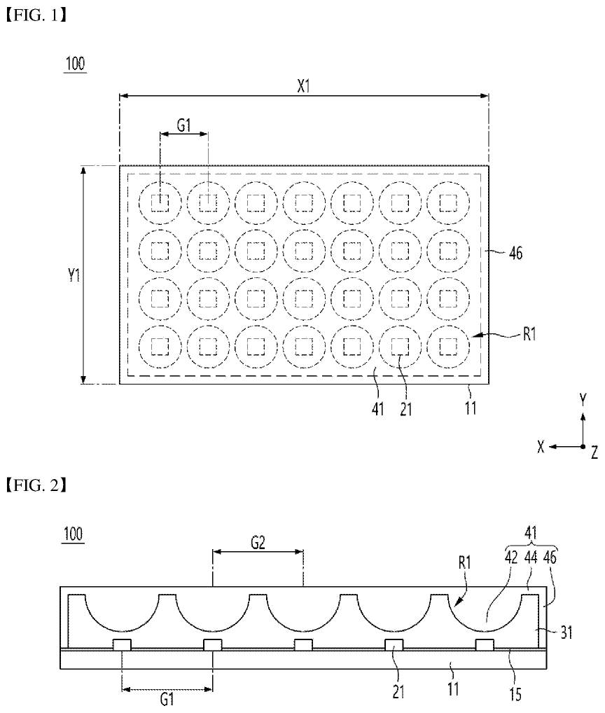

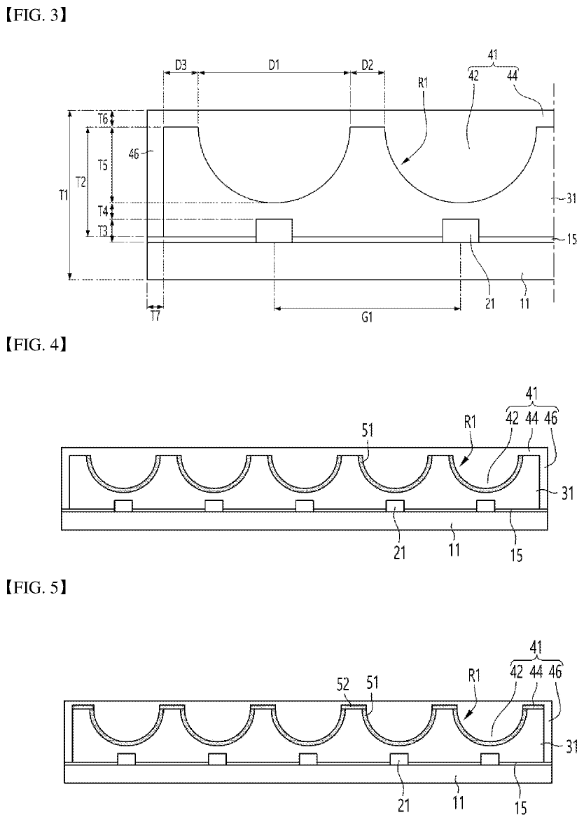

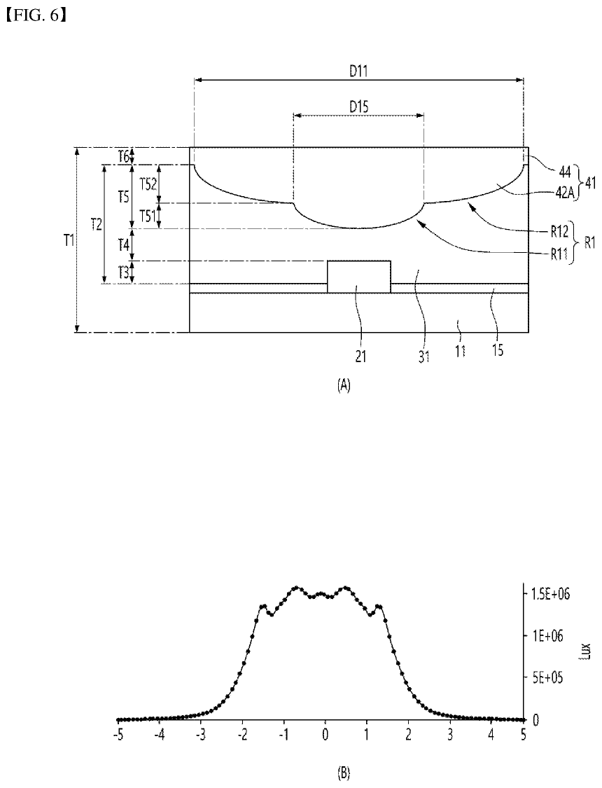

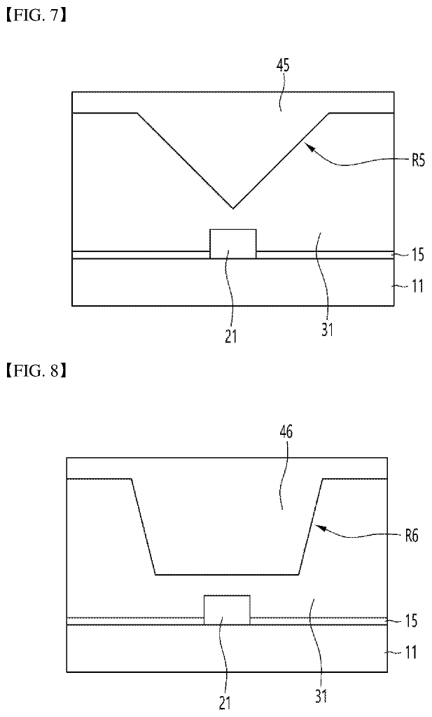

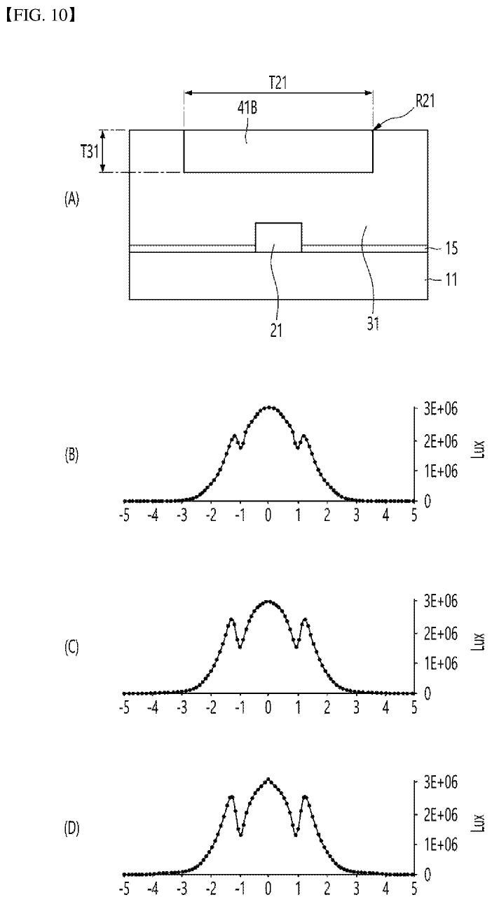

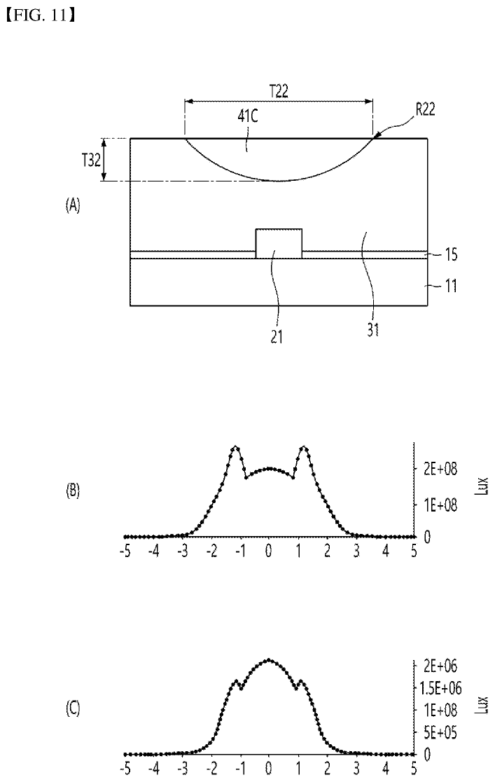

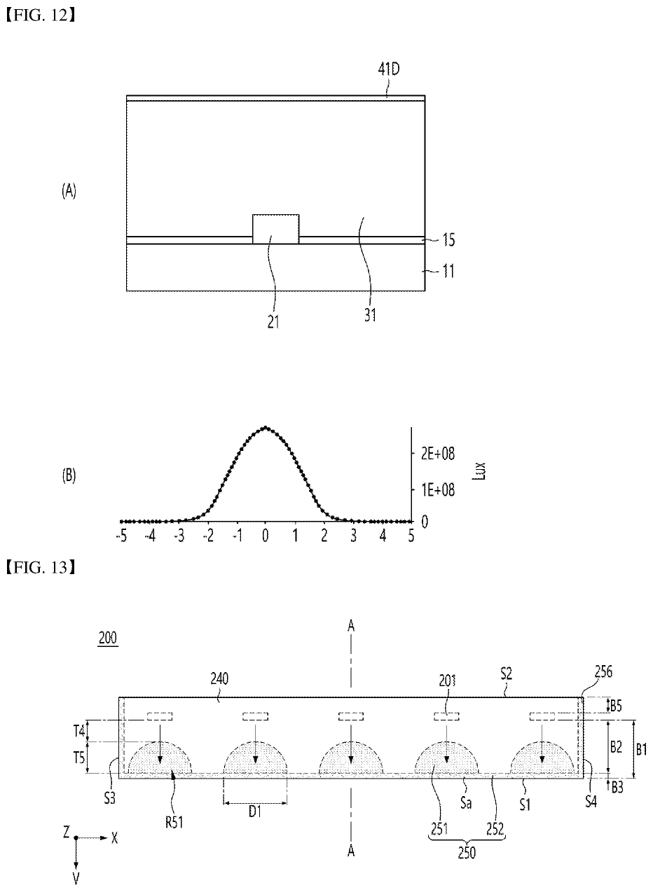

FIG. 1 is a plan view showing a lighting device according to a first embodiment of the invention, FIG. 2 is a side cross-sectional view of the lighting device of FIG. 1, FIG. 3 is a partially enlarged view of the lighting device of FIG. 2, FIG. 4 is another example of the lighting device of FIG. 2, FIG. 5 is another example of the lighting device of FIG. 4, FIG. 6 is a side cross-sectional view and a luminous intensity graph showing a modified example of the diffusion layer in the lighting device of FIG. 2, FIGS. 7 to 9 are examples of diffusion layers of different shapes in a lighting device according to an embodiment of the invention, FIG. 10(A) shows that a recess portion of the lighting device in the embodiment of the invention has a polygonal shape, and (B), (C) and (D) is a diagram comparing the luminous intensity of the lighting device according to the depth of the recess portion of FIG. 10(A), FIG. 11(A) shows that a recess portion of the lighting device in the embodiment of the invention has a semi-elliptical shape, and (B) and (C) is a diagram comparing the luminous intensity of the lighting device according to the depth of the recess portion in FIG. 11(A), and FIG. 12 (A) is a lighting device in a comparative example, and (B) is a diagram showing the luminous intensity of the lighting device in FIG. 12 (A).

Referring to FIGS. 1 to 3, a lighting device 100 may include a substrate 11, a light emitting device 21 disposed on the substrate 11, a resin layer 31 covering the light emitting device 21 on the substrate 11, and a diffusion layer 41 covering the resin layer 31. The lighting device 100 may be defined as a lighting module having a plurality of light emitting devices 21.

The resin layer 31 may include a recess portion R1 concave toward the light emitting device 21 from the other surface and overlapping the light emitting device 21 in a first direction. The first direction Z may be the optical axis direction of the light emitting device 21 or an axis direction with the highest luminous intensity. The plurality of recess portions R1 may be equal to the number of the light emitting devices 21 or may overlap with each light emitting device 21. The lighting device 100 may emit light emitted from the light emitting device 21 as uniformly distributed surface light. The lighting device 100 may be a flexible or rigid module.

As shown in FIG. 1, in the lighting device 100, the plurality of light emitting devices 21 may be arranged in N number in the second direction X (N is an integer of 2 or more) and M number in the third direction Y (M is an integer of 1 or more). The second direction X and the third direction Y are perpendicular to each other and may be perpendicular to the first direction Z. The plurality of light emitting devices 21 may be arranged in a line shape or a matrix shape having N×M. The lighting device 100 may be provided as a flexible module assembled to a bracket or housing having an inclination or curved surface. The lighting device 100 may emit at least one of green, blue, yellow, white, or red light. For example, the lighting device 100 may emit red light or white light. The light emitting device 21 may emit red light or white light. The light emitting device 21 may be an LED chip that emits red light, or may include an LED chip that emits blue light and a yellow phosphor layer.

The substrate 11 may include a printed circuit board (PCB), for example, a resin-based printed board (PCB), a metal core PCB, a flexible PCB, a ceramic PCB, or an FR-4 substrate. The substrate 11 may include, for example, a flexible PCB. The upper surface of the substrate 11 has an X axis-Y axis plane, and a thickness of the substrate 11 may be in a third direction Z or height orthogonal to the second and third X and Y. The substrate 11 includes a wiring layer (not shown) at the upper portion, and the wiring layer may be electrically connected to the light emitting device 21. The plurality of light emitting devices 21 may be connected in series, parallel, or series-parallel by the wiring layer of the substrate 11. The substrate 11 may function as a base member or support member located under the light emitting device 21 and the resin layer 31. A length X1 of the substrate 11 in the second direction X and a length Y1 of the substrate 11 in the third direction Y may be the same or different from each other. The thickness of the substrate 11 may be 0.5 mm or less, for example, in a range of 0.3 mm to 0.5 mm. Since the substrate 11 is provided with a thin thickness, the thickness of the lighting device 100 may be slimmed and softened. The thickness T1 of the lighting device 100 is a distance from one side to the other side in the first direction Z and may be less than 3 mm, for example, in a range of 2 mm to 2.6 mm or 2 mm to 2.4 mm. The thickness T1 of the lighting device 100 may be a straight distance between a lower surface of the substrate 11 and an upper surface of the diffusion layer 41. The thickness T1 of the lighting device 100 may be less than twice the thickness T2 of the resin layer 41, for example, in a range of 1.4 to 1.9 times.

When the thickness T1 of the lighting device 100 is thinner than the above range, light diffusion control may be difficult, and when the thickness T1 is greater than the above range, spatial installation restrictions and design freedom may be reduced. In an embodiment of the invention, the lighting device 100 has a thin thickness T1, for example, less than 3 mm, and can provide uniform luminance distribution.

The substrate 11 may have a connector in a portion to supply power to the light emitting devices 21. A region of the substrate 11 where the connector is disposed may be a region where a resin layer is not formed. The substrate 11 may have a top view shape of a rectangle, a square, or another polygonal shape. The substrate 11 may have a bar shape having a long straight line or a curved shape in one direction. The substrate 11 may include a protective layer or a reflective layer on the upper portion. The protective layer or reflective layer may include a member made of a solder resist material, and the solder resist material is a white material and may reflect incident light.

The light emitting device 21 may be disposed on the substrate 11 and sealed with the resin layer 31. The light emitting device 21 emits light through the resin layer 31. The resin layer 31 may be in contact with the upper surface and a plurality of side surfaces of the light emitting device 21. Each light emitting device 21 may include an LED chip that emits light through a plurality of side surfaces and an upper surface, and may be provided as a flip chip, for example. The light emitting device 21 may be electrically connected to the substrate 11. The light emitting device 21, for example, an LED chip, may emit light in a range of 630 nm to 750 nm, or may emit blue light in the range of 420 nm to 470 nm. When a phosphor layer is disposed on a surface of an LED chip, the phosphor may emit, for example, yellow light in the range of 630 nm to 750 nm. Accordingly, red light or white light may be emitted from the surface of the lighting device 100.

When the diffusion layer 41 is disposed on the resin layer 31, the light diffused through the resin layer 31 may be emitted in a uniform distribution. As another example, the light emitting device 21 may include a horizontal LED chip or a vertical LED chip. In the case of a horizontal chip or a vertical chip, the light emitting device 21 is connected to another chip or wiring pattern with a wire, so a thickness of the resin layer may increase due to a height of the wire and a connection space depending on a length of the wire may be increased. Because it is necessary, a distance between the light emitting devices 21 may be increased. As another example, the light emitting device 21 may be provided in a package having an LED chip.

The light emitting device 21 may be formed to have a thickness (T3, FIG. 3) of 0.3 mm or less. In the light emitting device 21 according to an embodiment of the invention, a beam angle distribution may increase due to five-sided light emission, and accordingly, a pitch G1 between the light emitting devices 21 may be greater than the thicknesses T2 (T2<G1) of the resin layer 31, and may be, for example, 4 mm or more or in the range of 4 mm to 8 mm. The pitch G1 may vary depending on the size of the LED chip. When the light emitting devices 21 are arranged in an N×M matrix on the substrate 11, they may provide uniform light diffused throughout the entire region. The light emitting device 21 may be sealed with a transparent insulating layer or a layer of resin material on its surface. The light emitting device 21 may have a phosphor layer having a phosphor on its surface. The light emitting device 21 may have a support member having a ceramic support member or a metal plate disposed at a lower portion, and the support member may be used as an electrically conductive and heat conductive member.

The resin layer 31 may be disposed on the substrate 11. The resin layer 31 seals the light emitting devices 21 on the substrate 11. The resin layer 31 may be adhered to the upper surface of the substrate 11. The resin layer 31 may be formed of silicone, epoxy, or UV resin. The refractive index of the resin layer 31 may be 1.8 or less, for example, in the range of 1.1 to 1.8 or 1.4 to 1.6, and may be lower than the refractive index of a diffusion agent. The resin layer 31 may be attached to the upper surface of the substrate 11 with an adhesive or may be directly attached. The resin layer 31 may be formed on the substrate 11 by, for example, a transfer molding method. The resin layer 31 may be formed of a transparent material that does not contain impurities such as diffusion agents, phosphors, and ink particles.

The resin layer 31 may have a thickness T2 greater than the thickness T3 of the light emitting device 21. The thickness T2 of the resin layer 31 may be thicker than the thickness of the substrate 11, and may be 6 times or less, for example, 3 to 6 times thicker than the thickness of the substrate 11. Since the resin layer 31 has the thickness T2, the resin layer 31 may seal the light emitting device 21 on the substrate 11 to prevent moisture from penetrating and support the substrate 11. The resin layer 31 and the substrate 11 may be made of flexible plates. The thickness T2 of the resin layer 31 may be less than 2 mm, for example, in a range of 1 mm to 1.9 mm or 1 mm to 1.7 mm. The thickness T2 of the resin layer 31 may be thicker than the thickness of the diffusion layer 41 and thicker than the thickness of the substrate 11. The thickness T2 of the resin layer 31 may be a distance or maximum interval between one side adjacent to the substrate 11 and the other side adjacent to the surface of the diffusion layer 41. The resin layer 31 may include a recess portion R1 that is concave from the other side toward one side or toward each light emitting device 21. A plurality of recess portions R1 may correspond to each light emitting device 21. Each of the recess portions R1 may overlap each light emitting device 21 in the first direction Z. a center of each recess portion R1 may overlap the center of each light emitting device 21 in the first direction Z. The diffusion layer 41 may be disposed in the recess portion R1.

The recess portion R1 may have a shape whose width increases as it moves away from a region adjacent to each light emitting device 21. Each of the recess portions R1 may have a circular outer shape. A side cross section of each recess portion R1 may have a semi-elliptical shape, a hemispherical shape, or a polygonal shape. The depth T5 of the recess portion R1 may be 60% or more of the thickness T2 of the resin layer 31, for example, in a range of 60% to 72% or 64% to 70%. When a depth T5 of the recess portion R1 is smaller than the above range, a light diffusion effect may be reduced, and when it is larger than the above range, the luminous intensity may be reduced. In addition, the maximum depth T5 of each recess portion may be in the range of 12% to 41% of a distance (i.e., optical axis distance) from one side of the resin layer 31 to the other side of the diffusion layer 41 in the direction in which light is emitted. The recess portion R1 may have a curved surface, for example, a radius of curvature of the curved surface may be 0.5 mm or more, for example, in the range of 0.5 mm to 6 mm, or may include the range of 0.5 mm to 4 mm. The interval T4 between a low point of the recess portion R1 and the light emitting device 21 may be smaller than the depth T5 of the recess portion R1, for example, 0.2 mm or more, 0.2 mm to 0.8 mm, or in the 0.2 mm to 0.5 mm range. When the interval T4 is smaller than the above range, the luminous intensity may decrease or the surface of the LED chip may damage, and when it is larger than the above range, the diffusion effect may be reduced. That is, the minimum distance T4 from one side of the resin layer 31 facing the substrate 11 to the recess portion R1 may be in a range of 0.7 to 1.5 times the thickness T3 of the light emitting device 21.

The lighting device 100 may include a reflective member 15 disposed between the substrate 11 and the resin layer 31. The reflective member 15 may not overlap the light emitting device 21 in the vertical direction. The reflective member 15 may overlap the resin layer 31 in the vertical direction. The reflective member 15 may be attached to the upper surface of the substrate 11 with an adhesive or may be directly attached. The reflective member 15 may be a reflective sheet or may include reflective resin. The reflective member 15 may be formed of a resin material containing silicon or epoxy, or may have a high refractive index filler, reflective agent, or absorber added thereto. The filler may include at least one of PMMA (Poly Methyl Meth Acrylate) series, TiO₂, SiO₂, Al₂O₃, and silicon series. The filler has a refractive index in the range of 1.4 to 2 at the emission wavelength, and its size may be in the range of 4 μm to 6 μm. The surface color of the reflective member 15 may be white. As another example, the reflective member 15 may be provided as an absorbing member, and the absorbing member may include a filler such as graphite in a resin material such as silicone or epoxy. This absorbing member may absorb light around each light emitting device 21 and prevent unnecessary light interference. The reflective member 15 may be removed when the surface material of the substrate 21 is a reflective layer.

The resin layer 31 seals the reflective member 15. The resin layer 31 may be in contact with the surface of the reflective member 15.

The reflective member 15 may include a through hole into which each light emitting device 21 is inserted. Although a structure in which one light emitting device is inserted into each through hole is shown, two or three or more light emitting devices may be inserted. A shape of the through hole may be circular or polygonal. The reflective member 15 is located around each of the plurality of light emitting devices 21 and may reflect incident light. A height of the reflective member 15 may be disposed lower than the upper surface of the light emitting device 21 based on the upper surface of the substrate 11. The reflective member 15 may have impurities of a reflective material scattered on its surface, and the impurities may scatter or reflect the light of the light emitting device 21 and increase the uniformity of light.

The diffusion layer 41 may be disposed on the resin layer 31. The diffusion layer 41 may be disposed on the upper surface of the resin layer 31 and the recess portion R1. The diffusion layer 41 may include a plurality of protruding portions 42 disposed in the recess portions R1 and an extension portion 44 disposed on the upper surface of the resin layer 31. The protruding portions 42 may be in contact with the surfaces of the recess portions R1 and may be provided with the greatest thickness at a center of the light emitting device 21. Accordingly, the protruding portion 42 may lower a central luminous intensity of the light emitting device 21. The diffusion layer 41 may have a surface with a concavo-convex structure for light diffusion. The extension portion 44 of the diffusion layer 41 may connect the plurality of protruding portions 42 to each other. The diffusion layer 41 includes a side portion 46 disposed on a side surface of the resin layer 31, and the side portion 46 may extend from an upper end of the side surface of the resin layer 31 toward the substrate 11. The side portion 46 may be in contact with at least one or both of the substrate 11 and the reflective member 15.

The side portion 46 of the diffusion layer 41 extends to an outer side surface of the resin layer 31 and contacts the upper surface of the substrate 11 or the reflective member 15, thereby preventing moisture infiltration. The extension portion 44 and the side portion 46 of the diffusion layer 41 may diffuse light. The diffusion layer 41 may include a material such as silicon or epoxy. The diffusion layer 41 may have a refractive index in the range of 1.4 to 2, and may be higher than a refractive index of the resin layer 31. when the refractive index of the diffusion layer 41 is lower than the above range, the uniformity of light may be lowered, and when it is higher than the above range, the light transmittance may be reduced. Accordingly, the refractive index of the diffusion layer 41 is provided within the above range, so that light transmittance and light uniformity may be adjusted. The diffusion layer 41 may be defined as a layer that has a phosphor inside and diffuses light. The diffusion agent may include at least one of PMMA (Poly Methyl Meth Acrylate) series, TiO₂, SiO₂, Al₂O₃, and silicon series. The diffuser has a refractive index in the range of 1.4 to 2 at the emission wavelength, and its size may be in the range of 1 μm to 100 μm. The dispersing agent may have a spherical shape, but is not limited thereto.

A content of the diffusion agent in the diffusion layer 41 may be 5 wt % or more, for example, in a range of 5 wt % to 10 wt %, compared to a resin material forming the diffusion layer 41. Accordingly, a diffusion efficiency of the diffusion layer 41 may not deteriorate even at the thicknesses T6 and T7 of the extension portion 44 and the side portion 46. The thicknesses T6 and T7 of the extension portion 44 and the side portion 46 may be 0.8 mm or less, for example, in a range of 0.3 mm to 0.8 mm, or in a range of 0.4 mm to 0.6 mm. Here, a center distance G2 between the recess portions R1 may be equal to a pitch G1 between the light emitting devices 21. A depth T5 of the recess portion R1 is the maximum depth and may be smaller than the maximum width D1. The maximum width D1 may be greater than the thickness T1 of the lighting device 100 and may be 2.5 mm or more, for example, in a range of 2.5 mm to 6 mm or 2.5 mm to 5 mm. When the maximum width D1 is smaller than the above range, the light diffusion effect may be reduced or the pitch G1 between the light emitting devices 21 may be narrowed, and when it is larger than the above range, the luminous intensity may be reduced. A ratio (T5:D1) between the maximum depth T5 and the maximum width D1 may range from 1:3.5 to 1:5.5. Since the maximum width D1 of the recess portion R1 is provided to be wider than 2.5 mm, light traveling to the upper portion of the light emitting devices 21 may be effectively diffused. Here, a sum (T2+T6) of the thicknesses from one side of the resin layer 31 to the other side of the diffusion layer 41 in the direction in which light is emitted from the lighting device 200 may be less than the maximum width D1 or 2 mm or less.

The distance D2 between the recess portions R1 is provided in a form in which the upper portion of the resin layer 31 protrudes, and the distance D2 at this time is smaller than the depth T5 of the recess portions R1, and may be provided in a range of 0.5 mm±0.2 mm. When the distance D2 is smaller than the above range, molding process of the resin layer 31 may be difficult or a boundary of the recess portions R1 may not be clear. A distance D3 between the recess portion R1 and the side surface may be in a range of 0.5 mm±0.2 mm and may support a circumference of the recess portion R1. The diffusion layer 41 is filled in the recess portions R1 of the resin layer 31, the thickness T2 of the resin layer 31 may be reduced to less than 3 mm, and the thickness T1 of the lighting device 100 may be minimized. In the embodiment of the invention, the lighting device 100 may be provided as a surface light source by using a minimum resin layer to have a minimum thickness. Additionally, the resin layer 31 and the diffusion layer 41 may be provided without a phosphor.

As shown in FIG. 4, a high refractive layer 51 may be disposed between the diffusion layer 41 and the resin layer 31. The high refractive layer 51 may be disposed between the protruding portion 42 of the diffusion layer 41 and the surface of the recess portions R1 of the resin layer 31. The high refractive layer 51 may be equal to or higher than the refractive index of the diffusion layer 41 and may be higher than the refractive index of the resin layer 31. The high refractive layer 51 may be made of a resin material such as silicone or epoxy, and a diffusion agent may be added thereto. A content of the diffusion agent in the high refractive layer 51 may be 7 wt % to 15 wt %. The high refractive layer 51 may be formed to a thickness of 0.5 mm or less on the surface of the recess portion R1, and may diffuse or refract incident light. The high refractive layer 51 is formed on the surface of the recess portions R1, as shown in FIG. 4, or may be further disposed on the surface of the recess portions R1 and disposed between the upper surface of the resin layer 31 and the extension portion 44 of the diffusion layer 41, as shown in FIG. 5.

In the embodiment of the invention, the shape of the recess portion R1 is described as a hemispherical shape or a semi-elliptical shape, but it may be provided in other shapes as shown in FIGS. 6 to 11. As shown in FIG. 6(A), the recess portion R1 of the resin layer 31 may include a double recess structure. The recess portion R1 may include a lower first recess portion R11 and an upper second recess portion R12. The protruding portions 42A of the diffusion layer 41 may be disposed in the first and second recess portions R11 and R12.

The first recess portion R11 may have a first maximum width D15 and may be formed to a first depth T51 at a lower end of the second recess portion R12, and the second recess portion R12 may be formed to a second depth T52 at the upper end of the resin layer 31. The first depth T51 may be greater than the second depth T52 and may range from 1.1 to 1.3 times the second depth T52. The depth T5 of the recess portion R1 may be smaller than the maximum width D11 of the recess portion R1 and may be smaller than the maximum width D15 of the first recess portion R11. The maximum width D15 of the first recess portion R11 may be 30% or more, for example, 30% to 40% of the maximum width D11 of the recess portion R1.

The first recess portion R11 may have a curved surface having a first radius of curvature, and the second recess portion R12 may have a curved surface having a radius of curvature greater than the first radius of curvature. The inflection point or critical point between the first recess portion R11 and the second recess portion R12 may be a boundary point between the curved surface of the first recess portion R11 and the curved surface of the second recess portion R12. The first radius of curvature of the first recess portion R11 may be 50% or more smaller than the second radius of curvature of the second recess portion R12. Accordingly, the first recess portion R11 may diffuse light incident on a narrow region into a sharply curved surface, and the second recess portion R12 may diffuse light incident on a wide region into a gently curved surface.

The graph in FIG. 6(B) shows the luminous intensity in a structure of the recess portion of FIG. 6(A), where a horizontal axis represents a distance (mm) from the optical axis and a vertical axis represents a luminous intensity (Lux). As shown in FIG. 6(B), it may be seen that the luminous intensity above a certain level is provided in a uniform distribution up to a certain region based on the optical axis.

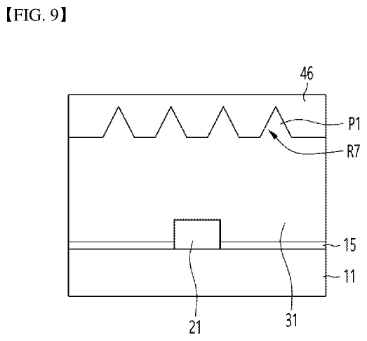

As shown in FIG. 7, the resin layer 31 may include a horn-shaped recess portion R5. The recess portion R5 may have a cone shape or a polygonal pyramid shape with a width that gradually narrows toward the lowest point at a bottom. A diffusion layer 45 may be disposed on the resin layer 31 and in the recess portion R5, and the diffusion layer 45 may diffuse incident light. As shown in FIG. 8, the resin layer 31 may include a polygon-shaped recess portion R6. The recess portion R6 may have a lower width less than an upper width, and may have an inverted trapezoidal shape. A diffusion layer 46 may be disposed on the resin layer 31 and in the recess portion R6, and the diffusion layer 46 may diffuse incident light. As shown in FIG. 9, as another example of the recess portion R7, the diffusion layer 46 may be disposed within the recess portion R7 having a plurality of polygonal patterns. The recess portion R7 having the plurality of polygonal patterns may have two or more patterns disposed on the light emitting device 21. Accordingly, the upper portions P1 of the resin layer 31 may protrude between the patterns, respectively. This diffusion layer 46 may provide a light diffusion effect because regions with different thicknesses are arranged on each light emitting device 21 by the patterns.

FIGS. 10 to 12 are diagrams comparing luminous intensity according to the shape and depth of the recess portions R21 and R22 in the embodiment of the invention.

As shown in FIG. 10(A), when the recess portion R21 has a polygonal side cross-section, for example, in a rectangular shape and a structure filled with the diffusion layer 41B, when a width T21 of the recess portion R21 is 1 mm and a depth T31 is 0.1 mm, it may be obtained as a result of the luminous intensity of FIG. 10(B), and when a width T21 is 1 mm and a depth T31 is 0.2 mm, it may be obtained as a result of the luminous intensity of FIG. 10(C), when a width T21 is 1 mm and a depth T31 is 0.3 mm, it may be obtained as a result of the luminous intensity of FIG. 10(D). At this time, it may be seen that the luminous intensity improves as the width is fixed and the depth T31 of the polygon shape increases.

As shown in FIG. 11(A), when the recess portion R22 is a curved surface with a concave side cross section, for example, in a semi-elliptical shape filled with the diffusion layer 41C, when a width T22 is 1 mm, a depth T32 is 0.3 mm, it may be obtained as a result of the luminous intensity in FIG. 11(B). When a width T22 is 2 mm and a depth T32 is 0.3 mm, it may be obtained as the result of the luminous intensity in FIG. 11(C). At this time, it may be seen that the luminous intensity improves as the width T22 and the depth T32 of the semi-elliptical recess portion R22 increase.

FIG. 12 shows that when the resin layer 31 forms a diffusion layer 41D having a constant thickness without a recess portion, as shown in FIG. 12(A) of the comparative example, it may be seen that the luminous intensity distribution is lower than that of in the embodiment of the invention, as shown in FIG. 12(B).

Therefore, in the embodiment of the invention, a recess portion having a semi-elliptical shape is disposed on the upper portion of the resin layer 31 and the diffusion layer 41 is filled, uniform surface light may be provided without a decrease in the light distribution emitted from the light emitting device 21 and the thickness of the lighting device 100 may be reduced to less than 3 mm.

The lighting device according to the second embodiment will refer to FIGS. 13 to 15, and the same or similar configuration as the first embodiment will refer to the description of the first embodiment, and can be selectively applied to this embodiment. there is.

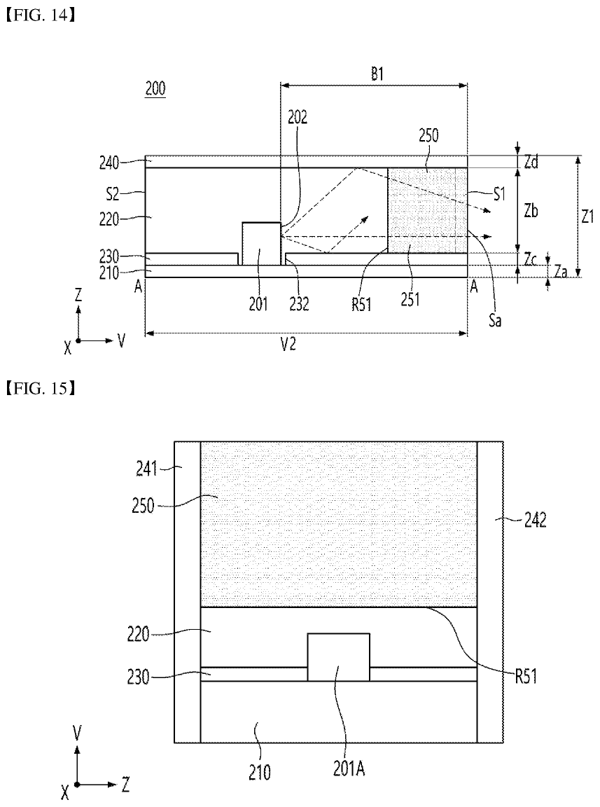

Referring to FIGS. 13 and 14, the lighting module or device 200 may include a substrate 210, a resin layer 220, a diffusion layer 250, and a plurality of light emitting devices 201. The lighting device 200 may have a second reflective member 240 disposed on at least one or both of the resin layer 220 and the diffusion layer 250. The lighting device 200 may include a first reflective member 230 under at least one or both of the resin layer 220 and the diffusion layer 250. The first reflective member 230 may be disposed on the substrate 210 and under the resin layer 220. The first and second reflective members 230 and 240 are respectively disposed on and under perpendicular to a first direction V of the resin layer 220 and may reflect incident light. The first direction V may be the direction in which light travels or the optical axis direction.

The light emitted from the light emitting device 201 may be irradiated in the form of surface light through at least one of the side surfaces of the resin layer 220 or through the diffusion layer 250. The lighting device 200 may have line-shaped side(s), an exit surface, or a transparent surface disposed around the plurality of light emitting devices 201. The lighting device 200 may be provided with an exit surface having a certain height or thickness on one surface facing the light emitting surface of the plurality of light emitting devices 201. The resin layer 220 may have at least one side and one side (or upper surface) exposed, and the diffusion layer 250 may have at least one side and one side (or upper surface) or/and the other side (or lower surface) exposed.

The lighting device 200 may include a first surface S1 and a second surface S2 disposed on opposite sides of each other, and a third surface S3 and a fourth surface S4 disposed on opposite sides of each other. The first and second surfaces S1 and S2 may extend to a long length in the second direction X, and the third and fourth surfaces S3 and S4 may extend to a long length in the first direction V. The first and second directions V and X may be perpendicular to each other or may intersect each other at an acute or obtuse angle. The third direction Z may be a vertical direction or a thickness direction and may be perpendicular to the first and second directions V and X.

In the lighting device 200, at least a portion of the first surface S1 and the second surface S2 may be disposed to face each other or be offset from each other. At least a portion of the third surface S3 and the fourth surface S4 may be disposed to face each other or be offset from each other. The third surface S3 and the fourth surface S4 may be different sides from the first surface S1 and the second surface S2. The minimum distance between the first and second surfaces S1 and S2 may be smaller than the minimum distance between the third and fourth surfaces S3 and S4.

In the lighting device 200, the first surface S1 and the second surface S2 may have a long length in one direction or a second direction X and may extend long in a bar shape or a line shape. The first surface S1 may face the light emitting surface 202 of the light emitting device 201 or may be a surface from which light with the highest luminous intensity is emitted among the side surfaces of the resin layer 220 or the diffusion layer 250. The first surface S1 may be an exit surface Sa. Here, the light emitting device 201 has been described as having a single-directional side as the light emitting surface 202, but it may emit light from two or more sides or more than four sides depending on a type of device or light source.

In the lighting device 200, the plurality of light emitting devices 201 may be arranged in the second direction X or may be arranged along a region adjacent to the second surface S2. The plurality of light emitting devices 201 may be arranged in one row. The virtual line connecting the light emitting devices 201 arranged in one row may be a straight line or may include a curve. As another example, the plurality of light emitting devices may be disposed in two rows, and the light emitting devices in the first row and the second row may be disposed not to overlap each other in a column direction (e.g., a V direction) between the first surface S1 and the second surface S2. The plurality of light emitting devices 201 arranged in the second direction X may each face the first surface S1 or the first exit surface. Each light emitting surface 202 of the plurality of light emitting devices 201 may face the first exit surface or the first surface S1. Light emitted from the light emitting device 201 is emitted through the first surface S1, and some light may be emitted through the second surface S2, third surface S3, and/or fourth surface S4.

The length of the lighting device 200 in the second direction X may vary depending on a number of the light emitting devices 201 arranged, and may be, for example, 30 mm or more. The length V2 of the lighting device 200 in the first direction V may provide a region where light emitted from the light emitting device 201 is diffused and a region that protects a rear of the light emitting device 201. Here, the length V2 may be less than twice the pitch of the light emitting devices 201.

A distance B1 between the first surface S1 and an emission surface 202 of the light emitting device 201 and a distance B5 between the second surface S2 and the other surface of the light emitting device 201 may be different from each other. And, for example, it may have a relationship of B1>B5. The distance B5 between the light emitting device 201 and the second surface S2 may be 3 mm or less, for example, in the range of 1 mm to 3 mm. When the distance B5 between the light emitting device 201 and the second surface S2 is less than the above range, the region where moisture may penetrate or form a circuit pattern may be small, and when it is greater than the above range, the lighting device 200 may increase in size.

In the lighting device 200, the first surface S1, the second surface S2, the third surface S3, and the fourth surface S4 are provided as a plane perpendicular to the third direction Z, or at least one may include curved or inclined surfaces. The first surface S1, the second surface S2, the third surface S3, and the fourth surface S4 may have the same thickness or the same height in the third direction Z. For example, the first surface S1, which is the first exit surface, may be a vertical plane or may include a convex curved surface. The resin layer 220 may include the second surface S2, the third surface S3, and the fourth surface S4, and the diffusion layer 250 may include the first surface S1, the third surface S3 and the third surface S4.

A diffusion layer 250 may be disposed outside the resin layer 220. The first to fourth surfaces S1, S2, S3, and S4 may be the outermost surfaces of the resin layer 220 or the diffusion layer 250. The diffusion layer 250 may be disposed on the side of the first surface S1, or on part or the entire side of the third surface S3 or/and the fourth surface S4. When the diffusion layer 250 is in contact with the outer surface of the resin layer 220, an interface between the diffusion layer 250 and the resin layer 220 may be disposed along a region where the diffusion layer 250 is formed. The resin layer 220 may have a plurality of recess portions R51 concave toward each light emitting device 201 from one side. Each of the plurality of recess portions R51 may overlap each light emitting device 201 in the first direction V. The diffusion layer 250 is disposed outside the recess portion R51 and the resin layer 220. The recess portion R51 may have a hemispherical shape or a semi-elliptical shape. The diffusion layer 250 may include protruding portions 251 disposed in the recess portions R51, and an extension portion 252 connecting the protruding portions 251. The diffusion layer 250 may include side portions 256 disposed on both sides of the resin layer 220 in the longitudinal direction. For the recess portion R51 and the diffusion layer 250, refer to the description of the first embodiment.

The light emitting device 201 may be a blue or red LED chip, or may include a package in which the LED chip is packaged. For example, the light emitting device 201 may be a side view type package or a package having a light emitting surface 202 on one side. The pitch between the light emitting devices 201 may be 4 mm or more, for example, in a range of 4 mm to 15 mm.

A thickness Za of the substrate 210 may be smaller than a height of the light emitting device 201. The height of the light emitting device 201 may be more than twice the thickness Za of the substrate 210, for example, in a range of 2 to 4 times. Since the thickness Za of the substrate 210 is thin, the lighting module 200 may be provided as a flexible plate. The resin layer 220 may cover the light emitting device 201 on the substrate 210. The second reflective member 240 may cover the upper surface of the resin layer 220. The resin layer 220 may contact the upper and side surfaces of the light emitting device 201. The resin layer 220 may be in contact with the upper surface of the first reflective member 230. A portion of the resin layer 220 may contact the substrate 210 through the hole 232 of the first reflective member 230. The resin layer 220 may be in contact with the light emitting surface 202 of the light emitting device 201. The first surface S1, second surface S2, third surface S3, and fourth surface S4 of the resin layer 220 may be side surfaces between the first and second reflective members 230 and 240.

An area of the upper surface area of the resin layer 220 may be the same as an area of the upper surface of the substrate 210, an area of the upper surface of the first reflective member 230, or an area of the lower surface of the second reflective member 240. A width of the resin layer 220 in the first direction V may be the same as a width of the substrate 210, a width of the first reflective member 230, or/and a width of the second reflective member 240. A length of the resin layer 220 in the second direction X may be the same as a length of the substrate 210, a length of the first reflective member 230, or/and a length of the second reflective member 240.

The resin layer 220 may be disposed between the first and second reflective members 230 and 240. A portion of the resin layer 220 may be disposed between the substrate 210 and the second reflective member 240. The upper surface of the first reflective member 230 and the lower surface of the second reflective member 240 may face each other at the upper and lower surfaces of the resin layer 220. The upper surface of the first reflective member 230 and the lower surface of the second reflective member 240 may have the same area. Accordingly, the resin layer 220 may diffuse the light emitted from the light emitting device 201 and the light reflected by the first and second reflective members 230 and 240 and guide them in the lateral direction.

The resin layer 220 may be formed to have a thickness Zb or height greater than the height of the light emitting device 201. Accordingly, the resin layer 220 may protect the upper part of the light emitting device 201 and suppress moisture penetration. Since the substrate 210 is disposed under the light emitting device 201 and the resin layer 220 is disposed above the light emitting device 201, the light emitting device 201 may be protected. Accordingly, a distance between the upper surface of the resin layer 220 and the light emitting device 201 may be 0.5 mm or less, for example, in the range of 0.2 mm to 0.5 mm. The thickness Zb of the resin layer 220 is a distance between the first and second reflective members 230 and 240, and a distance (e.g., Zb) between the first and second reflective members 230 and 240 may be smaller than a distance between the first surface S1 and the second surface S2. By arranging the lighting device 200 to have a small thickness in the third direction Z, it is possible to provide line-shaped surface light, improve luminance, and prevent hot spots. Additionally, flexible lighting modules may be provided.

The thickness Zb of the resin layer 220 may be two times or less than the thickness of the light emitting device 201, for example, may be greater than one time and less than or equal to two times. The thickness Zb of the resin layer 220 may be, for example, in the range of 1.5 mm to 1.9 mm or 1.5 mm to 1.6 mm. The thickness Zb of the resin layer 220 may be 0.8 times or less than the thickness Z1 of the lighting device 200, for example, in a range of 0.4 to 0.8 times the thickness Z1 of the lighting device 200. Since the resin layer 220 is disposed with a difference of 1.2 mm or less from the device Z1 of the lighting module 200, a decrease in light efficiency in the lighting module 200 may be prevented and ductility characteristics may be strengthened.

The first reflective member 230 may reflect light emitted from the light emitting device 201. The first reflective member 230 may be formed on the upper surface of the substrate 210. The first reflective member 230 may be formed as an upper layer of the substrate 210 or as a separate layer. The first reflective member 230 may be attached to the upper surface of the substrate 210 with an adhesive. The resin layer 220 may be adhered to the upper surface of the first reflective member 230. The first reflective member 230 has a plurality of holes 232 in a region corresponding to the lower surface of each of the light emitting devices 201, and the light emitting devices 201 may be connected to the substrate 210 through the holes 232. A portion of the resin layer 220 may contact the substrate 210 through the hole 232. The hole 232 may be a region where the light emitting device 201 is bonded to the substrate 210.

The first reflective member 230 may be formed as a single-layer or multi-layer structure. The first reflective member 230 may include a material that reflects light, such as a metal or non-metallic material. When the first reflective member 230 is made of metal, it may include a metal layer such as stainless steel, aluminum (Al), or silver (Ag), and when it is made of a non-metal material, it may be made of white resin. The resin may be a material filled with metal oxide and/or air, or may include a plastic material. The first reflective member 230 may be made of a white resin material or a polyester (PET) material. The first reflective member 230 may include at least one of a low-reflection film, a high-reflection film, a diffuse reflection film, or a regular reflection film. For example, the first reflective member 230 may be provided as a regular reflection film to reflect incident light onto the first surface S1.

One end of the first reflective member 230 may be disposed on the same plane as the first surface S1. The other end of the first reflective member 230 may be disposed on the same plane as the second surface S2. The thickness Zc of the first reflective member 230 may be smaller than the thickness Za of the substrate 210. The thickness Zc of the first reflective member 230 is arranged to be 0.3 times or more than the thickness Za of the substrate 210, thereby reducing the transmission loss of incident light. The thickness Zc of the first reflective member 230 may range from 0.1 mm to 0.3 mm. When it is smaller than the above range, light transmission loss may occur, and when it is thicker than the above range, the thickness Z1 of the lighting module 200 may increase.

The thickness Zd of the second reflective member 240 may be smaller than the thickness Za of the substrate 210. The thickness Zd of the second reflective member 240 is disposed to be 0.3 times or more than the thickness Za of the substrate 210, thereby reducing the transmission loss of incident light. The thickness Zd of the second reflective member 240 may range from 0.1 mm to 0.3 mm. When it is smaller than the above range, light transmission loss may occur, and when it is thicker than the above range, the thickness Z1 of the lighting module 200 may increase. The second reflective member 240 is disposed on the entire upper surface of the resin layer 220, and may reduce light loss. The second reflective member 240 may be made of the same material as the first reflective member 230. The second reflective member 240 may be made of a material with a higher light reflectance or may have a greater thickness than the material of the first reflective member 230 in order to reflect light and reduce light transmission loss. The second reflective member 240 may be the same thickness as the first reflective member 230 or may be thicker. For example, the first and second reflective members 230 and 240 may be made of the same material and have the same thickness.

The second reflective member 240 may be formed as a single-layer or multi-layer structure. The second reflective member 240 may include a material that reflects light, such as a metal or non-metallic material. When the second reflective member 240 is made of metal, it may include a metal layer such as stainless steel, aluminum (Al), or silver (Ag). When it is made of a non-metal material, it may be made of white resin or may contain metal oxide and/or in the resin. The resin may be a material filled with metal oxide and/or air, or may include a plastic material. The second reflective member 240 may be made of white resin or polyester (PET). The second reflective member 240 may include at least one of a low-reflection film, a high-reflection film, a diffuse reflection film, or a regular reflection film. For example, the second reflective member 240 may be provided as a regular reflection film so that the incident light travels in the direction of the first surface S1. Here, a light extraction structure such as a concavo-convex structure may be disposed on the first surface S1. Accordingly, the extraction efficiency of light emitted through the diffusion layer 250 may be improved. The lighting device 200 according to the embodiment of the invention can provide a surface light source with flexibility and a line shape by providing a thickness Z1 in the third direction Z in the form of a line.

The maximum depth T5 of each of the plurality of recess portions R51 is smaller than the maximum width D1 in at least one direction perpendicular to the first direction V, and the thickness Zb of the resin layer 220 may be smaller than the maximum width D1 of each recess portion R51 and greater than the maximum depth T5 of each recess portion R51. At this time, the height of the recess portion R51 in the third direction Z may be equal to the thickness Zb of the resin layer 220.

Referring to FIG. 14, comparing the thickness of each component in the lighting module 200, when the thickness of the substrate 210 is Za, the thickness of the resin layer 220 is Zb, the thickness of the first reflective member 230 is Zc, and the thickness of the second reflective member 240 is Zd, a relationship may be Zb>Za>Zd≥Zc. By arranging the thickness Zb of the resin layer 220 to be thicker than the thickness Za of the substrate 210, the light emitting device 201 may be protected, light may be diffused and guided, and ductility characteristics may be strengthened. Additionally, since a line-shaped exit surface Sa having the thickness Zb or height of the resin layer 220 is provided, light may be provided in a form of line light. The distance B1 between the emission surface 202 of the light emitting device 201 and the first surface S1 may be at least twice the thickness Zb or height of the resin layer 220, for example, in a range of 2 to 8 times. The diffusion layer 250 may be provided so that a thickness B3 of the extension portion 252 may be 0.7 mm or less, for example, in a range of 0.3 mm to 0.7 mm or 0.3 mm to 0.5 mm. The second embodiment of the invention reduces the thickness of the lighting device 200 and emits slim line light through the side surface. At this time, the line light may be emitted as a uniform surface light source through the exit surface Sa by the recess portion R51 and the diffusion layer 250.

As shown in FIGS. 15 and 13, in the lighting device, a substrate 210 and a first reflective member 230 may be disposed behind the exit surface of the resin layer 220, and a recess portion R51 and a diffusion layer 250 disclosed in the embodiment may be disposed at the front. The recess portion R51 may have a hemispherical shape or a semi-elliptical shape. In this structure, the second and third reflective members 241 and 242 are disposed on both sides of the first direction V to reflect the light emitted from the light emitting device 201A. Accordingly, the light emitted through the diffusion layer 250 is reflected and diffused, and may be provided in the form of line light with uniform light distribution. The light emitting device 201A may be implemented as a flip chip type light emitting device as shown in FIGS. 1 to 3.

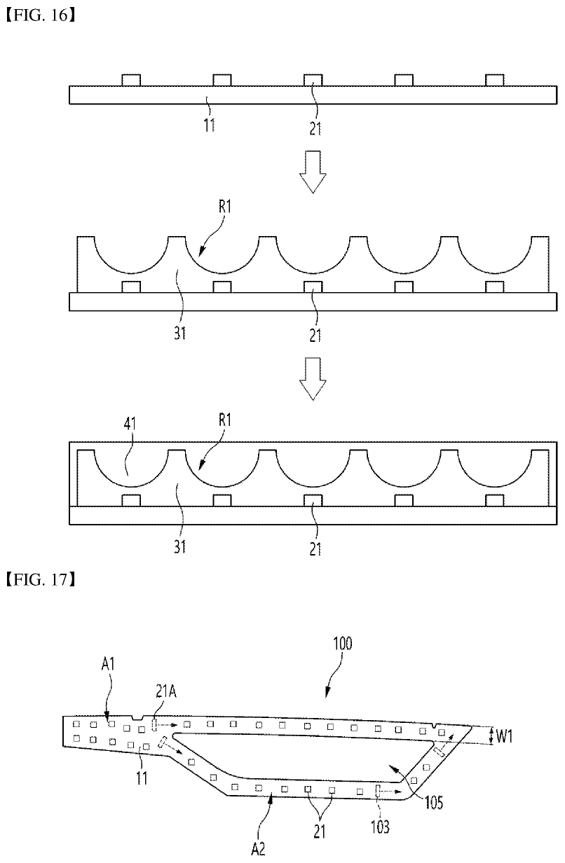

As shown in FIG. 16, to describe the manufacturing process of the lighting device, a plurality of light emitting devices 21 are mounted on the substrate 11 on which the reflective member is disposed, and when the resin layer 31 is molded using a transfer method, the recess portion R1 is formed together. Afterwards, a diffusion layer 41 is formed on the resin layer 31. In addition, in the structure of FIGS. 13 to 15, after the resin layer and diffusion layer are formed, reflective member(s) may be attached to one or both sides in the first direction.

As shown in FIG. 17, the lighting device arranges the top-view type first light emitting device 21 in an entire region of the substrate 11, and mainly arrange the first light emitting devices 21 in the first and second regions A1 and A2 having a wide or narrow width W1, and a side view type light emitting device 21A may be further disposed at the entrance or exit side of the narrow second region A2, or at a portion where the substrate is bent or curved. Accordingly, uniform light distribution may be provided in the entire region and the occurrence of dark part may be suppressed. An opening portion 105 may be disposed inside the substrate 11.

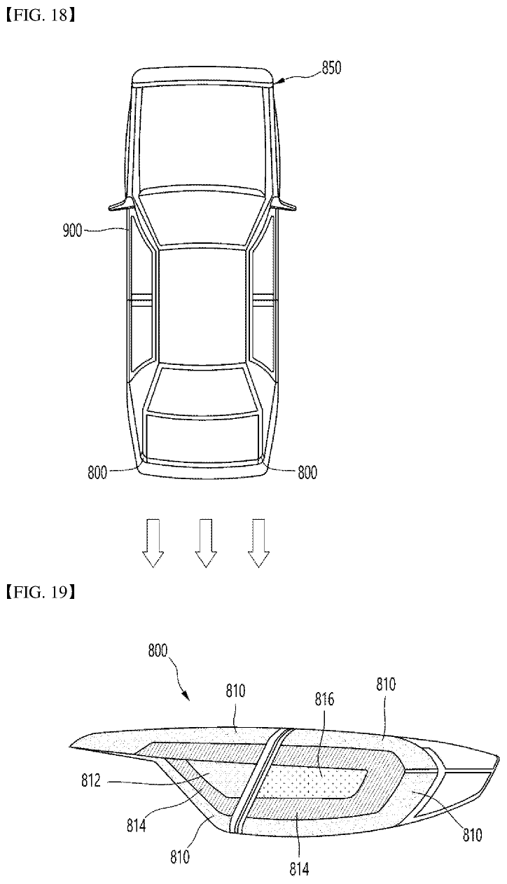

FIG. 18 is a plan view of a vehicle equipped with a vehicle lamp to which a lighting module is applied according to an embodiment, and FIG. 19 is a view showing a vehicle lamp having a lighting module or lighting device disclosed in an embodiment.

Referring to FIGS. 18 and 19, in the vehicle 900, a tail light 800 may include a first lamp unit 812, a second lamp unit 814, a third lamp unit 816, and a housing 810. Here, the first lamp unit 812 may be a light source to serve as a turn signal, the second lamp unit 814 may be a light source to serve as a sidelight, and the third lamp unit 816 may be a light source to serve as a brake light, but is not limited to this. At least one or all of the first to third lamp units 812, 814, and 816 may include the lighting module disclosed in the embodiment. The housing 810 accommodates the first to third lamp units 812, 814, and 816, and may be made of a light-transmitting material. At this time, the housing 810 may have a curve depending on the design of the vehicle body, and the first to third lamp units 812, 814, and 816 may implement a surface light source that may have a curved surface depending on the shape of the housing 810. These vehicle lamps may be applied to a vehicle's turn signal lamp when the lamp unit is applied to a vehicle's tail light, brake light, or turn signal lamp.

Features, structures, effects, etc. described in the above embodiments are included in at least one embodiment of the invention, and are not necessarily limited to only one embodiment. Furthermore, features, structures, effects, etc. illustrated in each embodiment can be combined or modified for other embodiments by those of ordinary skill in the art to which the embodiments belong. Accordingly, the contents related to such combinations and modifications should be interpreted as being included in the scope of the invention. In addition, although the embodiments have been mainly described above, this is only an example and does not limit the present invention, and one of ordinary skill in the field to which the present invention belongs will appreciate that various modifications and applications not illustrated above may be possible without departing from the essential characteristics of the present embodiment. For example, each component specifically shown in the embodiment can be implemented by modification. And differences related to such modifications and applications should be construed as being included in the scope of the invention defined in the appended claims.

1. A lighting device comprising:
a substrate;
a plurality of light emitting devices disposed on the substrate;
a resin layer disposed on the substrate and sealing the plurality of light emitting devices; and
a diffusion layer on the resin layer,
wherein the resin layer includes a plurality of recess portions that are concave toward each of the plurality of light emitting devices,
wherein the diffusion layer includes a plurality of protruding portions disposed in each of the plurality of recess portions,
wherein each of the plurality of protruding portions is spaced apart in a first direction in which light is emitted from each light emitting device,
wherein a maximum depth of each of the plurality of recess portions is smaller than a maximum width of each of the plurality of recess portions in at least one direction perpendicular to the first direction, and
wherein a thickness of the resin layer is smaller than the maximum width of each recess portion and greater than the maximum depth of each recess portion.

2. The lighting device of claim 1, wherein the maximum depth of each recess portion in the first direction is in a range of 12% to 41% of an optical axis distance from one side of the resin layer to the other side of the diffusion layer in the first direction.

3. The lighting device of claim 1, wherein each recess portion has a shape whose width increases from a region closest to each light emitting device to a distance from each light emitting device.

4. The lighting device of claim 3, wherein the shape of each recess portion has a hemispherical shape, a semi-elliptical shape, or a double curved shape in a side cross section.

5. The lighting device of claim 1, wherein the diffusion layer includes an extension portion connecting a plurality of protruding portions on the resin layer.

6. The lighting device of claim 5, wherein the diffusion layer includes a side portion extending to each side of the resin layer,
wherein the resin layer and the diffusion layer are provided without a phosphor.

7. A lighting device comprising:
a first reflective member;
a second reflective member facing the first reflective member;
a resin layer disposed between the first and second reflective members;
a plurality of light emitting devices sealed in the resin layer and emitting light through one side between the first and second reflective members; and
a diffusion layer disposed on a portion of an outer side of the resin layer,
wherein the resin layer includes a plurality of recess portions that are concave from one side of the resin layer toward each of the plurality of light emitting devices,
wherein the diffusion layer includes a plurality of protruding portions disposed in each of the plurality of recess portions,
wherein each of the plurality of protruding portions is spaced apart in a first direction in which light is emitted from each light emitting device,
wherein a maximum depth of each of the plurality of recess portions is smaller than a maximum width of each of the plurality of recess portions in at least one direction perpendicular to the first direction, and
wherein a thickness of the resin layer is smaller than the maximum width of each recess portion and greater than the maximum depth of each recess portion.

8. The lighting device of claim 7, wherein the diffusion layer includes an extension portion connecting the plurality of protruding portions,
wherein the protruding portion and the extension portion provide an exit surface through which light is emitted.

9. The lighting device of claim 8, wherein the diffusion layer includes side portions extending on both sides of the resin layer in a longitudinal direction.

10. The lighting device of claim 7, comprising:
a refractive layer disposed on a surface of the recess portions and having a higher refractive index than that of a material of the resin layer or the diffusion layer.

11. A lighting device comprising:
a substrate;
a plurality of light emitting devices disposed on the substrate;
a resin layer disposed on the substrate and sealing the plurality of light emitting devices; and
a diffusion layer disposed on the resin layer and having a diffusion agent,
wherein the resin layer includes a first surface on an exit side and a second surface on the opposite side of the first surface,
wherein the resin layer includes a plurality of recess portions concave from the first surface toward each of the plurality of light emitting devices,
wherein the diffusion layer includes a plurality of protruding portions disposed in each of the plurality of recess portions,
wherein the resin layer and the diffusion layer are stacked in a first direction,
wherein the plurality of light emitting devices are arranged in a second direction perpendicular to the first direction,
wherein the plurality of protruding portions is arranged in the second direction,
wherein each of the plurality of protruding portions is spaced apart from each light emitting device in the first direction,
wherein a maximum depth of each of the plurality of recess portions is smaller than a maximum width of each of the recess portions in the second direction,
wherein the plurality of light emitting devices overlap the plurality of protruding portions in the first direction, and
wherein each of the plurality of light emitting devices is disposed between the second surface of the resin layer and each of the plurality of recess portions.

12. The lighting device of claim 11,
wherein a minimum distance between the light emitting device and the second surface of the resin layer is smaller than a minimum distance between the light emitting device and the recess portion.

13. The lighting device of claim 11,
wherein a length of each of the light emitting devices in the second direction is smaller than the maximum width of each of the recess portions in the second direction.

14. The lighting device of claim 11,
wherein a thickness of the resin layer is smaller than the maximum width of each recess portion.

15. The lighting device of claim 11,
wherein a thickness of the resin layer is greater than the maximum depth of each of the recess portions.

16. The lighting device of claim 11,
wherein a width of each recess portion in the second direction is minimum in a region adjacent to each light emitting device and maximum in a region adjacent to the first surface of the resin layer.

17. The lighting device of claim 16,
wherein each of the recess portions has a concave curved surface.

18. The lighting device of claim 11,
wherein the diffusion layer is disposed on the first surface of the resin layer and includes an extension portion connecting the plurality of protruding portions to each other.

19. The lighting device of claim 18,
wherein a thickness of the extension portion in the first direction is smaller than a maximum thickness of each of the protruding portions.

20. The lighting device of claim 11, comprising:
a refractive index layer having a higher refractive index than a refractive index of the resin layer and disposed on a surface of the recess portions.
